(19) United States
(12) Patent Application Publication
(10) Pub. No.: US 2024/0353904 A1
(43) Pub. Date: Oct. 24, 2024

(54) Cryogenic Cooling System Configuration for Multi-Unit Scaling for Quantum Computing Systems

(71) Applicant: Google LLC, Mountain View, CA (US)

(72) Inventor: Vladimir Shvarts, Ventura, CA (US)

(21) Appl. No.: 18/543,345

(22) Filed: Dec. 18, 2023

Related U.S. Application Data
(60) Provisional application No. 63/433,557, filed on Dec. 19, 2022.

(51) Int. Cl. G06F 1/20; F25D 19/04

(52) U.S. Cl. CPC G06F 1/20; F25D 19/04

(57) ABSTRACT

Cryogenic cooling systems for use in quantum computing applications are provided. In one example, the cryogenic cooling system may include a plurality of stages. Each stage may be associated with an operating temperature. Each stage may be progressively cooler when moving from a first stage of the plurality of stages to a subsequent stage of the plurality of stages. The first stage of the plurality of stages may be associated with an operating temperature of about 60 kelvin or greater.

### PRIORITY CLAIM

The present application is based on and claims priority to U.S. Provisional Application 63/433,557 having a filing date of Dec. 19, 2022, which is incorporated by reference herein.

### FIELD

The present disclosure relates generally to cryogenic cooling systems, and, more particularly, to cryogenic cooling systems for quantum computing systems.

### BACKGROUND

Quantum computing is a computing method that takes advantage of quantum effects, such as superposition of basis states and entanglement to perform certain computations more efficiently than a classical digital computer. In contrast to a digital computer, which stores and manipulates information in the form of bits, e.g., a “1” or “0,” quantum computing systems may manipulate information using quantum bits (“qubits”). A qubit may refer to a quantum device that enables the superposition of multiple states, e.g., data in both the “0” and “1” state, and/or to the superposition of data, itself, in the multiple states. In accordance with conventional terminology, the superposition of a “0” and “1” state in a quantum system may be represented, e.g., as a |0 [symbol] +b|1 [symbol] The “0” and “1” states of a digital computer are analogous to the |0and |1basis states, respectively of a qubit.

### SUMMARY

Aspects and advantages of embodiments of the present disclosure will be set forth in part in the following description, or may be learned from the description, or may be learned through practice of the embodiments.

One example aspect of the present disclosure is directed to a cryogenic cooling system for a quantum computing system. The cryogenic cooling system may include a plurality of stages. Each stage may be associated with an operating temperature. Each stage may be progressively cooler when moving from a first stage of the plurality of stages to a subsequent stage of the plurality of stages. The first stage of the plurality of stages may be associated with an operating temperature of about 60 kelvin or greater.

Other aspects of the present disclosure are directed to various systems, methods, apparatuses, non-transitory computer-readable media, computer-readable instructions, and computing devices.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, explain the related principles.

### BRIEF DESCRIPTION OF THE DRAWINGS

Detailed discussion of embodiments directed to one of ordinary skill in the art is set forth in the specification, which refers to the appended figures, in which:

FIG. 1 depicts an example quantum computing system according to example embodiments of the present disclosure;

FIG. 2 depicts an example quantum computing system according to example embodiments of the present disclosure;

FIG. 3 depicts an example cryogenic cooling system for a quantum computing system according to example embodiments of the present disclosure; and

FIG. 4 depicts an example quantum computing system comprising a plurality of cryogenic cooling systems according to example embodiments of the present disclosure.

### DETAILED DESCRIPTION

Example aspects of the present disclosure are directed to cryogenic cooling system(s) (e.g., cryostat(s)) that may be employed, for example, in quantum computing applications. For instance, the cryogenic cooling system(s) may be configured to cool one or more quantum systems having a plurality of qubits (e.g., superconducting qubits) operable to process and/or perform quantum computations.

Many quantum computing applications employ superconducting qubits that achieve superconductivity, or zero electrical resistance, at temperatures around approximately absolute zero, or about 0 kelvin. A challenge associated with quantum computing includes cooling quantum hardware with the superconducting qubits to a temperature at which the superconducting qubits achieve superconductivity. For example, in some cases, the superconducting qubits must be cooled to less than about 0.1 kelvin, such as about 0.01 kelvin, or about 10 millikelvin or less. Quantum computing systems may employ a cryogenic cooling system, such as a dilution refrigerator, to cool the superconducting qubits and/or other quantum hardware. The cryogenic cooling systems may form a “vacuum canister” having subsequent progressive temperature stages ranging from a temperature on the order of about 100 K to about 10 mK.

A challenge in quantum computing relates to communications between a supercooled quantum system (e.g., qubits) and a classical computing system (e.g., a binary computing system). Quantum computing systems may be at least partially controlled by a classical computing system. The classical computing system may be kept separate from the quantum computing system and may be maintained at a higher temperature than the quantum computing system such as, for instance, at about room temperature. Quantum computing systems may require fast and robust communications between the classical computing system and the quantum system (e.g., qubits) to precisely and reliably implement quantum gate operations and/or quantum state measurements. To address this requirement, many systems employ physical signal lines, such as wires, between the classical computing system and quantum system. These physical signal lines must then connect to the quantum systems and thus form a thermal conductor between the classical computing system and quantum system. The physical signal lines may reduce the efficiency of a cryogenic cooling system configured to cool the quantum system.

According to example aspects of the present disclosure, a cryogenic cooling system may include a plurality of cryogenic cooling stages having an associated operating temperature or operating temperature range. The plurality of cryogenic cooling stages may include, for instance, a first stage, a second stage, a third stage, a fourth stage, a fifth stage, a sixth stage, and/or a seventh stage. Each stage may be cooled to progressively lower and lower temperatures (e.g., progressively cooler). In some embodiments, the first stage may be associated with a temperature of about 60 kelvin or greater, such as about 80 kelvin or greater, such as in a range of about 80 kelvin to about 100 kelvin.

In some embodiments, the second stage may be associated with a temperature in a range of about 40 kelvin to about 60 kelvin. In some embodiments, the third stage may be associated with a temperature in a range of about 10 kelvin to about 20 kelvin, such as about 15 kelvin. In some embodiments, the fourth stage may be associated with a temperature in a range of about 2.5 kelvin to about 4.2 kelvin, such as about 3 kelvin. In some embodiments, the fifth stage may be associated with a temperature in a range of about 600 millikelvin to about 800 millikelvin, such as about 700 millikelvin. In some embodiments, the sixth stage may be associated with a temperature in a range of about 100 millikelvin to about 300 millikelvin, such as about 150 millikelvin. In some embodiments, the seventh stage may be associated with a temperature in a range of about 10 millikelvin to about 100 millikelvin, such as about 20 millikelvin. The quantum hardware (e.g., quantum processor with a plurality of superconducting qubits) may be located, for instance, at the seventh stage.

In some embodiments, a quantum computing system may have a plurality of quantum processors linked across a plurality of different cryogenic cooling systems. According to aspects of the present disclosure, the quantum computing system may include a plurality of cryogenic cooling systems arranged in, for instance, an array. Each cryogenic cooling system may be operable to cool one or more quantum processors of the quantum computing system. Each cryogenic cooling system may have matching stages (e.g., matching thermal plates) to provide consistent cooling stages across all of the plurality of cryogenic cooling systems.

In some embodiments, one or more of the plurality of stages at each of the plurality of cryogenic cooling systems may include a wiring port. The wiring port may provide for the connection of wiring signals among one or more consistent cooling stages of the plurality of cryogenic cooling systems. For instance, a first stage of a first cryogenic cooling system may include a wiring port for connection to a wiring port of a first stage of a second cryogenic cooling system. A second stage of the first cryogenic cooling system may include a wiring port for connection to a wiring port of a second stage of the second cryogenic cooling system. A third stage of the first cryogenic cooling system may include a wiring port for connection to a wiring port of a third stage of the second cryogenic cooling system. A fourth stage of the first cryogenic cooling system may include a wiring port for connection to a wiring port of a fourth stage of the second cryogenic cooling system. A fifth stage of the first cryogenic cooling system may include a wiring port for connection to a wiring port of a fifth stage of the second cryogenic cooling system. A sixth stage of the first cryogenic cooling system may include a wiring port for connection to a wiring port of a sixth stage of the second cryogenic cooling system. A seventh stage of the first cryogenic cooling system may include a wiring port for connection to a wiring port of a seventh stage of the second cryogenic cooling system.

In some embodiments, the first cryogenic cooling system may be associated with a different manufacturer relative to the second cryogenic cooling system. The port position allows the multiple cryogenic cooling systems to be arranged in an array that allows the qubits to be linked, and consistent cold stages across multiple different fridges avoids the need to customize wiring for the particular thermal profile of individual cryogenic cooling systems, thus making scaling achievable, even with multiple different manufacturers of the cryogenic cooling systems.

In some embodiments, each cryogenic cooling system may include a dilution refrigerator with series connected mixing stages including a first mixing stage and a second mixing stage. The first mixing stage may be associated with the coldest stage of the cryogenic cooling system (e.g., the stage where the quantum processor is located). The second mixing stage may be associated with one of the intermediate cooling stages of the cryogenic cooling system (e.g., not the first cooling stage or the last cooling stage).

As used herein, the use of the term “about” or “approximately” in conjunction with a stated numerical value is intended to refer to within 10% of the stated numerical value. As used herein, “near maximum” refers to within 10% of a maximum. As used herein, “near minimum” refers to within 10% of a minimum.

With reference now to the FIGS., example embodiments of the present disclosure will be discussed in further detail.

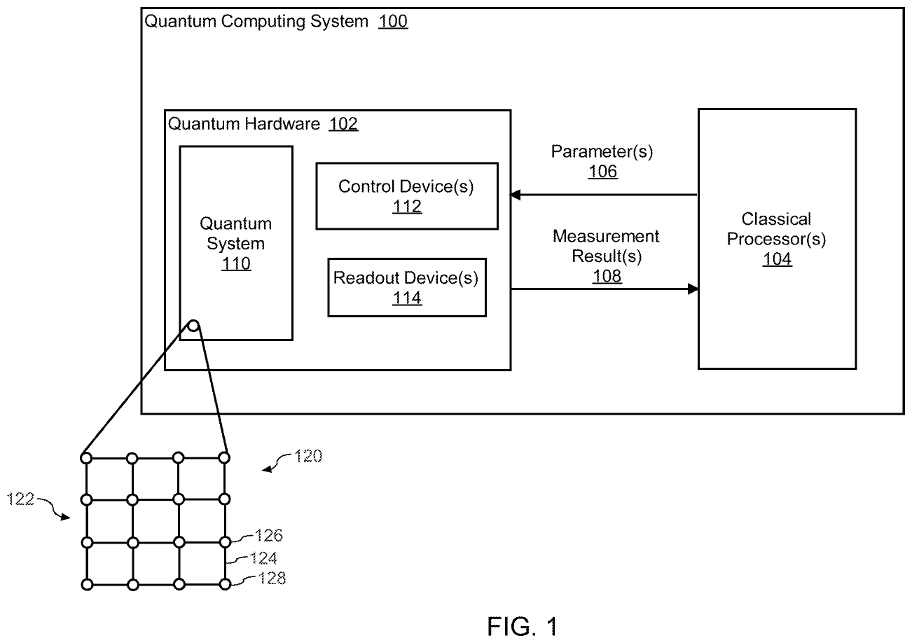

FIG. 1 depicts an example quantum computing system 100. The system 100 is an example of a system of one or more classical computers and/or quantum computing devices in one or more locations, in which the systems, components, and techniques described below can be implemented. Those of ordinary skill in the art, using the disclosures provided herein, will understand that other quantum computing devices or systems can be used without deviating from the scope of the present disclosure.

The system 100 includes quantum hardware 102 in data communication with one or more classical processors 104. The classical processors 104 can be configured to execute computer-readable instructions stored in one or more memory devices to perform operations, such as any of the operations described herein. The quantum hardware 102 includes components for performing quantum computation. For example, the quantum hardware 102 includes a quantum system 110, control device(s) 112, and readout device(s) 114 (e.g., readout resonator(s)). The quantum system 110 can include one or more multi-level quantum subsystems, such as a register of qubits (e.g., qubits 120). In some implementations, the multi-level quantum subsystems can include superconducting qubits, such as flux qubits, charge qubits, transmon qubits, gmon qubits, etc.

The type of multi-level quantum subsystems that the system 100 utilizes may vary. For example, in some cases it may be convenient to include one or more readout device(s) 114 attached to one or more superconducting qubits, e.g., transmon, flux, gmon, xmon, or other qubits. In other cases, ion traps, photonic devices or superconducting cavities (e.g., with which states may be prepared without requiring qubits) may be used. Further examples of realizations of multi-level quantum subsystems include fluxmon qubits, silicon quantum dots or phosphorus impurity qubits.

Quantum circuits may be constructed and applied to the register of qubits included in the quantum system 110 via multiple control lines that are coupled to one or more control devices 112. Example control devices 112 that operate on the register of qubits can be used to implement quantum gates or quantum circuits having a plurality of quantum gates, e.g., Pauli gates, Hadamard gates, controlled-NOT (CNOT) gates, controlled-phase gates, T gates, multi-qubit quantum gates, coupler quantum gates, etc. The one or more control devices 112 may be configured to operate on the quantum system 110 through one or more respective control parameters (e.g., one or more physical control parameters). For example, in some implementations, the multi-level quantum subsystems may be superconducting qubits and the control devices 112 may be configured to provide control pulses to control lines to generate magnetic fields to adjust the frequency of the qubits.

The quantum hardware 102 may further include readout devices 114 (e.g., readout resonators). Measurement results 108 obtained via measurement devices may be provided to the classical processors 104 for processing and analyzing. In some implementations, the quantum hardware 102 may include a quantum circuit and the control device(s) 112 and readout devices(s) 114 may implement one or more quantum logic gates that operate on the quantum system 102 through physical control parameters (e.g., microwave pulses) that are sent through wires included in the quantum hardware 102. Further examples of control devices include arbitrary waveform generators, wherein a DAC (digital to analog converter) creates the signal.

The readout device(s) 114 may be configured to perform quantum measurements on the quantum system 110 and send measurement results 108 to the classical processors 104. In addition, the quantum hardware 102 may be configured to receive data specifying physical control qubit parameter values 106 from the classical processors 104. The quantum hardware 102 may use the received physical control qubit parameter values 106 to update the action of the control device(s) 112 and readout devices(s) 114 on the quantum system 110. For example, the quantum hardware 102 may receive data specifying new values representing voltage strengths of one or more DACs included in the control devices 112 and may update the action of the DACs on the quantum system 110 accordingly. The classical processors 104 may be configured to initialize the quantum system 110 in an initial quantum state, e.g., by sending data to the quantum hardware 102 specifying an initial set of parameters 106.

In some implementations, the readout device(s) 114 can take advantage of a difference in the impedance for the |0 [symbol] and |1 [symbol] states of an element of the quantum system, such as a qubit, to measure the state of the element (e.g., the qubit). For example, the resonance frequency of a readout resonator can take on different values when a qubit is in the state |0 [symbol] or the state |1 [symbol] , due to the nonlinearity of the qubit. Therefore, a microwave pulse reflected from the readout device 114 carries an amplitude and phase shift that depend on the qubit state. In some implementations, a Purcell filter can be used in conjunction with the readout device(s) 114 to impede microwave propagation at the qubit frequency.

In some embodiments, the quantum system 110 can include a plurality of qubits 120 arranged, for instance, in a two-dimensional grid 122. For clarity, the two-dimensional grid 122 depicted in FIG. 1 includes 4×4 qubits, however in some implementations the system 110 may include a smaller or a larger number of qubits. In some embodiments, the multiple qubits 120 can interact with each other through multiple qubit couplers, e.g., qubit coupler 124. The qubit couplers can define nearest neighbor interactions between the multiple qubits 120. In some implementations, the strengths of the multiple qubit couplers are tunable parameters. In some cases, the multiple qubit couplers included in the quantum computing system 100 may be couplers with a fixed coupling strength.

In some implementations, the multiple qubits 120 may include data qubits, such as qubit 126 and measurement qubits, such as qubit 128. A data qubit is a qubit that participates in a computation being performed by the system 100. A measurement qubit is a qubit that may be used to determine an outcome of a computation performed by the data qubit. That is, during a computation an unknown state of the data qubit is transferred to the measurement qubit using a suitable physical operation and measured via a suitable measurement operation performed on the measurement qubit.

In some implementations, each qubit in the multiple qubits 120 can be operated using respective operating frequencies, such as an idling frequency and/or an interaction frequency(s) and/or readout frequency and/or reset frequency. The operating frequencies can vary from qubit to qubit. For instance, each qubit may idle at a different operating frequency. The operating frequencies for the qubits 120 can be chosen before a computation is performed.

FIG. 1 depicts one example quantum computing system that can be used to implement the methods and operations according to example aspects of the present disclosure. Other quantum computing systems can be used without deviating from the scope of the present disclosure.

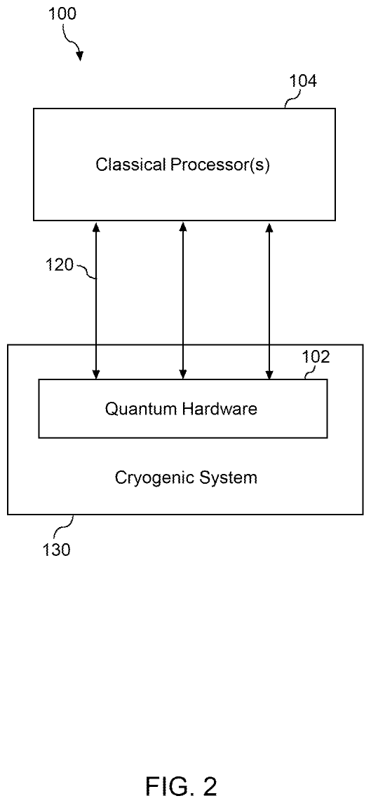

FIG. 2 depicts an example quantum computing system 100 according to example embodiments of the present disclosure. As illustrated in FIG. 2, quantum hardware 102, such as, but not limited to, quantum system 110, control device(s) 112, readout device(s) 114, and/or any other suitable components of quantum hardware 102 discussed with regard to FIG. 1, may be located within cryogenic cooling system 130. Additionally and/or alternatively, classical processor(s) 104 may be located outside cryogenic cooling system 130. For instance, cryogenic cooling system 130 may be configured to cool quantum hardware 102. Additionally and/or alternatively, classical processor(s) 104 are not cooled by cryogenic cooling system 130. For instance, classical processor(s) 104 may operate at temperatures around room temperature (e.g., around 300 kelvin), whereas quantum hardware 102 may operate at temperatures around absolute zero (e.g., less than about 1 kelvin) which may thus require cooling by cryogenic cooling system 130.

Quantum computing system 100 may include signal line(s) 120. The signal line(s) 120 may couple classical processor(s) 104 to quantum hardware 102. For instance, as classical processor(s) 104 and quantum hardware 102 may be in signal communication, such as to transmit parameter(s) 106 and/or measurement result(s) 108 of FIG. 1 in addition to any other suitable signals, the classical processor(s) 104 may be coupled to quantum hardware 102 by signal lines 120. For instance, signal lines 120 may be or may include any suitable physical communicative coupling(s) (e.g., one or more wires) that is/are configured to couple quantum hardware 102 and classical processor(s) 104. Generally, signal lines 120 include physical connections to allow for faster and/or more robust communication between quantum hardware 102 and classical processor(s) 104. As illustrated in FIG. 2, signal lines 120 may be at least partially located in cryogenic cooling system 130 to provide coupling to quantum hardware 102.

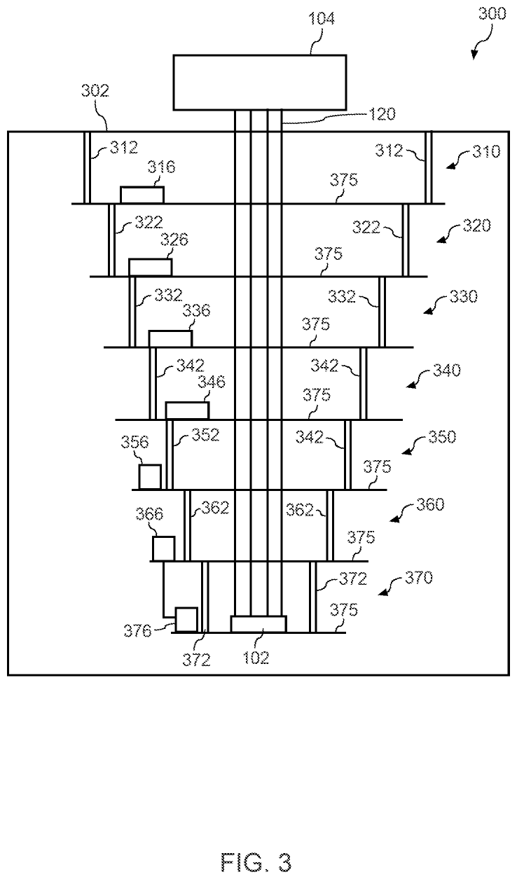

FIG. 3 depicts an example cryogenic cooling system 300 according to example embodiments of the present disclosure. The cryogenic cooling system 300 may be configured to cool the quantum hardware 102 (e.g., a quantum processor). For instance, the cryogenic cooling system 300 may cool the quantum hardware 102 to a temperature below about 1 kelvin. As one example, the cryogenic cooling system may cool the quantum hardware 102 to a temperature at which the quantum hardware 102 achieves superconductivity, such as at temperatures of about 10 millikelvin or less. Signal lines 120 may communicate signals between the classical processor(s) 104 and the quantum hardware 102.

As illustrated in FIG. 3, the cryogenic cooling system 300 may include a plurality of cryogenic cooling stages. The cryogenic cooling stages may include, for example, a first stage 310, a second stage 320, a third stage 330, a fourth stage 340, a fifth stage 350, a sixth stage 360 and a seventh stage 370. Each cooling stage may include a thermal plate that is coupled to a prior stage or a top plate 302 of the cryogenic cooling system 300 with one or more supports. Each thermal plate may be cooled to a particular temperature associated with the cooling stage by a cooling unit thermally coupled to the thermal plate. The signal lines 120 may be coupled to each thermal plate of each thermal stage through thermal clamps or other suitable thermal connection.

More particularly, in some examples, the cryogenic cooling system 300 may include a first stage 310. The first stage 310 may include, for example, a first thermal plate 315 coupled to a top plate 302 of the cryogenic cooling system 300 using one or more supports 312 (e.g., one or more column supports). The first thermal plate 315 may be a thermally conductive material, such as a metal. The first stage 310 may include a first cooling unit 316 thermally coupled to the first thermal plate 315. The first stage 310 may be associated with a temperature of about 60 kelvin or greater, such as about 80 kelvin or greater, such as in a range of about 80 kelvin to about 100 kelvin. For instance, in some embodiments, the first cooling unit 316 may be configured to cool the first thermal plate 315 to a temperature of about 60 kelvin or greater, such as about 80 kelvin or greater, such as in a range of about 80 kelvin to about 100 kelvin. In some embodiments, the first cooling unit 316 may include a pulse tube. The signal lines 120 may be coupled to the first thermal plate 315 through thermal clamps or other suitable thermal connection.

In some examples, the cryogenic cooling system 300 may include a second stage 320. The second stage 320 may include, for example, a second thermal plate 325 coupled to the first thermal plate 315 of the cryogenic cooling system 300 using one or more supports 322 (e.g., one or more column supports). The second thermal plate 325 may be a thermally conductive material, such as a metal. The second stage 320 may include a second cooling unit 326 thermally coupled to the second thermal plate 325. The second stage 320 may be associated with a temperature in a range of about 40 kelvin to about 60 kelvin For instance, in some embodiments, the second cooling unit 326 may be configured to cool the second thermal plate 325 to a temperature in a range of about 40 kelvin to about 60 kelvin. In some embodiments, the second cooling unit 326 may include a pulse tube. The signal lines 120 may be coupled to the second thermal plate 325 through thermal clamps or other suitable thermal connection.

In some examples, the cryogenic cooling system 300 may include a third stage 330. The third stage 320 may include, for example, a third thermal plate 335 coupled to the second thermal plate 325 of the cryogenic cooling system 300 using one or more supports 332 (e.g., one or more column supports). The third thermal plate 335 may be a thermally conductive material, such as a metal. The third stage 330 may include a third cooling unit 336 thermally coupled to the third thermal plate 335. The third stage 330 may be associated with a temperature in a range of about 10 kelvin to about 20 kelvin, such as about 15 kelvin. For instance, in some embodiments, the third cooling unit 336 may be configured to cool the third thermal plate 335 to a temperature in a range of about 10 kelvin to about 20 kelvin, such as about 15 kelvin. In some embodiments, the third cooling unit 3366 may include a pulse tube. The signal lines 120 may be coupled to the third thermal plate 335 through thermal clamps or other suitable thermal connection.

In some examples, the cryogenic cooling system 300 may include fourth stage 340. The fourth stage 340 may include, for example, a fourth thermal plate 345 coupled to the third thermal plate 335 of the cryogenic cooling system 300 using one or more supports 342 (e.g., one or more column supports). The fourth thermal plate 345 may be a thermally conductive material, such as a metal. The fourth stage 340 may include a fourth cooling unit 346 thermally coupled to the fourth thermal plate 345. The fourth stage 340 may be associated with a temperature in a range of about 2.5 kelvin to about 4.2 kelvin, such as about 3 kelvin. For instance, in some embodiments, the fourth cooling unit 346 may be configured to cool the fourth thermal plate 345 to a temperature in a range of about 2.5 kelvin to about 4.2 kelvin, such as about 3 kelvin. In some embodiments, the fourth cooling unit 346 may include a pulse tube. The signal lines 120 may be coupled to the fourth thermal plate 345 through thermal clamps or other suitable thermal connection.

In some examples, the cryogenic cooling system 300 may include a fifth stage 350. The fifth stage 350 may include, for example, a fifth thermal plate 355 coupled to the fourth thermal plate 345 of the cryogenic cooling system 300 using one or more supports 352 (e.g., one or more column supports). The fifth thermal plate 355 may be a thermally conductive material, such as a metal. The fifth stage 350 may include a fifth cooling unit 356 thermally coupled to the fifth thermal plate 355. The fifth stage 350 may be associated with a temperature in a range of about 600 millikelvin to about 800 millikelvin, such as about 700 millikelvin. For instance, in some embodiments, the fifth cooling unit 356 may be configured to cool the fifth thermal plate 355 to a temperature in a range of about 600 millikelvin to about 800 millikelvin, such as about 700 millikelvin. In some embodiments, the fifth cooling unit 356 may include a still of a dilution refrigerator (e.g., a ³He/⁴He dilution refrigerator). The signal lines 120 may be coupled to the fifth thermal plate 355 through thermal clamps or other suitable thermal connection.

In some examples, the cryogenic cooling system 300 may include a sixth stage 360. The sixth stage 360 may include, for example, a sixth thermal plate 365 coupled to the fifth thermal plate 355 of the cryogenic cooling system 300 using one or more supports 362 (e.g., one or more column supports). The sixth thermal plate 365 may be a thermally conductive material, such as a metal. The sixth stage 360 may include a sixth cooling unit 366 thermally coupled to the sixth thermal plate 365. The sixth stage 360 may be associated with a temperature in a range of about 100 millikelvin to about 300 millikelvin, such as about 150 millikelvin. For instance, in some embodiments, the sixth cooling unit 366 may be configured to cool the sixth thermal plate 365 to a temperature in a range of about 100 millikelvin to about 300 millikelvin, such as about 150 millikelvin. In some embodiments, the sixth cooling unit 366 may include a heat exchanger of a dilution refrigerator (e.g., a ³He/⁴He dilution refrigerator). In some embodiments, the sixth cooling unit 366 may include a first mixing chamber of a plurality of series connected mixing chambers of a dilution refrigerator (e.g., a ³He/⁴He dilution refrigerator). The signal lines 120 may be coupled to the sixth thermal plate 365 through thermal clamps or other suitable thermal connection.

In some examples, the cryogenic cooling system 300 may include a seventh stage 370. The seventh stage 370 may include, for example, a seventh thermal plate 375 coupled to the sixth thermal plate 365 of the cryogenic cooling system 300 using one or more supports 372 (e.g., one or more column supports). The seventh thermal plate 375 may be a thermally conductive material, such as a metal. The seventh stage 370 may include a seventh cooling unit 376 thermally coupled to the sixth thermal plate 375. The seventh stage 370 may be associated with a temperature in a range of about 100 millikelvin to about 300 millikelvin, such as about 150 millikelvin. For instance, in some embodiments, the sixth cooling unit 366 may be configured to cool the sixth thermal plate 365 to a temperature in a range of about 10 millikelvin to about 100 millikelvin, such as about 20 millikelvin. In some embodiments, the seventh cooling unit 376 may be a mixing chamber of a dilution refrigerator (e.g., a ³He/⁴He dilution refrigerator). In some embodiments, the seventh cooling unit 376 may be a second mixing chamber of a plurality of series connected mixing chambers of a dilution refrigerator (e.g., a ³He/⁴He dilution refrigerator). The quantum hardware may be located on or thermally coupled to the seventh thermal plate 375.

The cryogenic cooling system 300 may include a vacuum canister 305. The vacuum cannister 305 may house each of the plurality of cryogenic cooling stages and/or the quantum hardware 102. The vacuum canister 305 may be located in a vacuum and/or otherwise define a vacuum for the plurality of cryogenic cooling stages and/or the quantum hardware 102. For example, an airtight seal may be formed around the vacuum canister 305 and any air in the vacuum canister 305 may be purged from the vacuum canister 305.

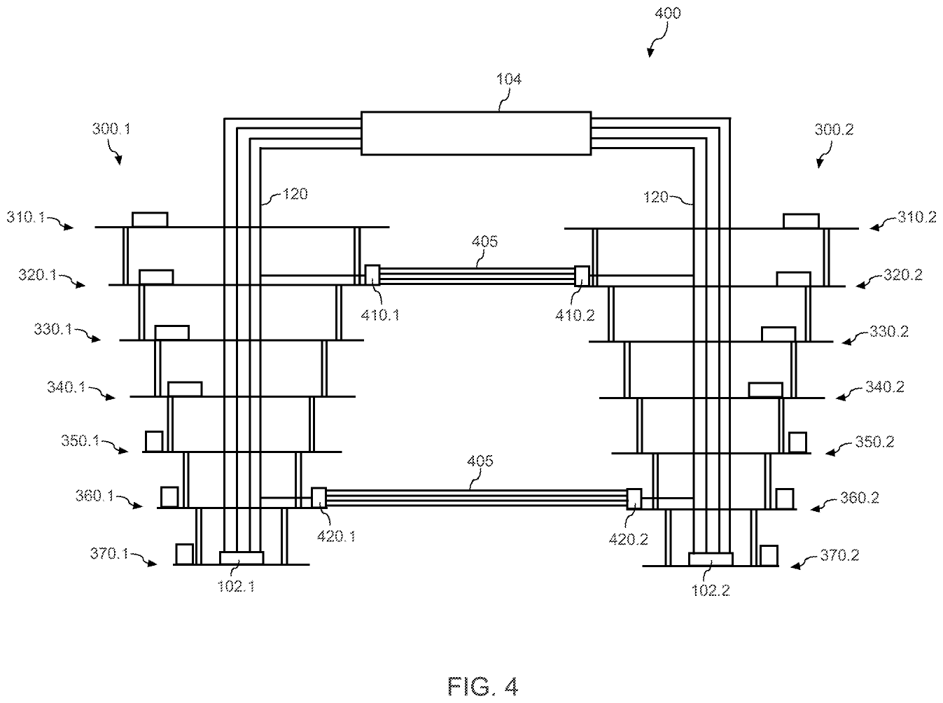

FIG. 4 depicts a quantum computing system 400 that includes a plurality of cryogenic cooling systems 300.1, 300.2 . . . 300.n according to example embodiments of the present disclosure. Two cryogenic cooling systems 300.1 and 300.2 are illustrated in FIG. 4 for purposes of illustration and discussion. The quantum computing system 400 may include additional cryogenic cooling systems without deviating from the scope of the present disclosure.

Each of the cryogenic cooling systems 300.1, 300.2, . . . 300.n may be configured to cool quantum hardware 102.1, 102.2 . . . 102.n having one or more superconducting qubits. The quantum computing system 400 provides for the linking of qubits across different cryogenic cooling systems 300. In some embodiments, the cryogenic cooling systems 300.1, 300.2, . . . 300.n may be associated with different manufacturers. In some examples, the cryogenic cooling systems 300.1, 300.2, . . . 300.n may be in the same vacuum canister. In some examples, the cryogenic cooling systems 300.1, 300.2, . . . 300.n may be in different vacuum canisters.

Each of the plurality of cryogenic cooling systems 300.1, 300.2, . . . 300.n may have a plurality of cooling stages. In some examples, each of the plurality of cryogenic cooling systems 300.1, 300.2, . . . 300.n has a similar configuration to the cryogenic cooling system 300 of FIG. 3.

In some embodiments, each of the cryogenic cooling systems 300.1, 300.2, . . . 300.n may have consistent cooling stages that are cooled to the same temperature range. For instance, the first stage 300.1 of the first cryogenic cooling system 300.1 may be associated with the same temperature as the first stage 300.2 of the second cryogenic cooling system 300.2. The second stage 320.1. of the first cryogenic cooling system 300.1 may be associated with the same temperature as the second stage 320.2 of the second cryogenic cooling system 300.2. The third stage 330.1. of the first cryogenic cooling system 300.1 may be associated with the same temperature as the third stage 330.2 of the second cryogenic cooling system 300.2. The fourth stage 340.1. of the first cryogenic cooling system 300.1 may be associated with the same temperature as the fourth stage 340.2 of the second cryogenic cooling system 300.2. The fifth stage 350.1. of the first cryogenic cooling system 300.1 may be associated with the same temperature as the fifth stage 350.2 of the second cryogenic cooling system 300.2. The sixth stage 360.1. of the first cryogenic cooling system 300.1 may be associated with the same temperature as the second stage 360.2 of the second cryogenic cooling system 300.2. The seventh stage 370.1. of the first cryogenic cooling system 300.1 may be associated with the same temperature as the seventh stage 370.2 of the second cryogenic cooling system 300.2. The consistent cold stages across multiple different cryogenic cooling systems 300.1, 300.2, . . . 300.n may reduce or avoid the need to customize wiring for the particular thermal profile of individual cryogenic cooling systems, thus making scaling achievable, even with multiple different manufacturers of the cryogenic cooling systems 300.1, 300.2, . . . 300.n.

Signal lines 120 may communicate signals between the classical processor(s) 104 and the quantum hardware 102. In some embodiments, one or more of the stages of the cryogenic cooling systems 300.1, 300.2, . . . 300.n may include a wiring port for communicating signals with a corresponding wiring port of a corresponding stage on a different cryogenic cooling system in the quantum computing system 400.

For instance, the second stage 320.1 of the first cryogenic cooling system 300.1 may include a wiring port 410.1. The second stage 320.2 of the second cryogenic cooling system 300.2 may include a wiring port 410.2. Signal lines 405 may be coupled between the wiring port 410.1 and wiring port 410.2. In some examples, the sixth stage 360.1 of the first cryogenic cooling system 300.1 may include a wiring port 420.1. The sixth stage 360.2 of the second cryogenic cooling system 300.2 may include a wiring port 420.2. Signal lines 405 may be coupled between the wiring port 420.1 and wiring port 420.2. In this way, the wiring ports 410.1, 410.2 and/or the wiring ports 420.1, 420.2 may provide for the connection of wiring signals among one or more consistent cooling stages of the plurality of cryogenic cooling systems.

FIG. 4 is discussed with reference to wiring ports at the second stage and the sixth stage for purposes of illustration and discussion. Those of ordinary skill in the art, using the disclosures provided herein, will understand that any stage or combination of stages of the cryogenic cooling systems 300.1, 300.2, . . . 300.n may include wiring ports without deviating from the scope of the present disclosure.

Implementations of the digital and/or quantum subject matter and the digital functional operations and quantum operations described in this specification may be implemented in digital electronic circuitry, suitable quantum circuitry or, more generally, quantum computational systems, in tangibly-implemented digital and/or quantum computer software or firmware, in digital and/or quantum computer hardware, including the structures disclosed in this specification and their structural equivalents, or in combinations of one or more of them. The term “quantum computing systems” may include, but is not limited to, quantum computers/computing systems, quantum information processing systems, quantum cryptography systems, or quantum simulators.

Implementations of the digital and/or quantum subject matter described in this specification may be implemented as one or more digital and/or quantum computer programs, i.e., one or more modules of digital and/or quantum computer program instructions encoded on a tangible non-transitory storage medium for execution by, or to control the operation of, data processing apparatus. The digital and/or quantum computer storage medium may be a machine-readable storage device, a machine-readable storage substrate, a random or serial access memory device, one or more qubits/qubit structures, or a combination of one or more of them. Alternatively or in addition, the program instructions may be encoded on an artificially-generated propagated signal that is capable of encoding digital and/or quantum information (e.g., a machine-generated electrical, optical, or electromagnetic signal) that is generated to encode digital and/or quantum information for transmission to suitable receiver apparatus for execution by a data processing apparatus.

The terms quantum information and quantum data refer to information or data that is carried by, held, or stored in quantum systems, where the smallest non-trivial system is a qubit, i.e., a system that defines the unit of quantum information. It is understood that the term “qubit” encompasses all quantum systems that may be suitably approximated as a two-level system in the corresponding context. Such quantum systems may include multi-level systems, e.g., with two or more levels. By way of example, such systems may include atoms, electrons, photons, ions or superconducting qubits. In many implementations the computational basis states are identified with the ground and first excited states, however it is understood that other setups where the computational states are identified with higher level excited states (e.g., qudits) are possible.

The term “data processing apparatus” refers to digital and/or quantum data processing hardware and encompasses all kinds of apparatus, devices, and machines for processing digital and/or quantum data, including by way of example a programmable digital processor, a programmable quantum processor, a digital computer, a quantum computer, or multiple digital and quantum processors or computers, and combinations thereof. The apparatus may also be, or further include, special purpose logic circuitry, e.g., an FPGA (field programmable gate array), or an ASIC (application-specific integrated circuit), or a quantum simulator, i.e., a quantum data processing apparatus that is designed to simulate or produce information about a specific quantum system. In particular, a quantum simulator is a special purpose quantum computer that does not have the capability to perform universal quantum computation. The apparatus may optionally include, in addition to hardware, code that creates an execution environment for digital and/or quantum computer programs, e.g., code that constitutes processor firmware, a protocol stack, a database management system, an operating system, or a combination of one or more of them.

A digital computer program, which may also be referred to or described as a program, software, a software application, a module, a software module, a script, or code, may be written in any form of programming language, including compiled or interpreted languages, or declarative or procedural languages, and it may be deployed in any form, including as a stand-alone program or as a module, component, subroutine, or other unit suitable for use in a digital computing environment. A quantum computer program, which may also be referred to or described as a program, software, a software application, a module, a software module, a script, or code, may be written in any form of programming language, including compiled or interpreted languages, or declarative or procedural languages, and translated into a suitable quantum programming language, or may be written in a quantum programming language, e.g., QCL, Quipper, Cirq, etc.

A digital and/or quantum computer program may, but need not, correspond to a file in a file system. A program may be stored in a portion of a file that holds other programs or data, e.g., one or more scripts stored in a markup language document, in a single file dedicated to the program in question, or in multiple coordinated files, e.g., files that store one or more modules, sub-programs, or portions of code. A digital and/or quantum computer program may be deployed to be executed on one digital or one quantum computer or on multiple digital and/or quantum computers that are located at one site or distributed across multiple sites and interconnected by a digital and/or quantum data communication network. A quantum data communication network is understood to be a network that may transmit quantum data using quantum systems, e.g. qubits. Generally, a digital data communication network cannot transmit quantum data, however a quantum data communication network may transmit both quantum data and digital data.

The processes and logic flows described in this specification may be performed by one or more programmable digital and/or quantum computers, operating with one or more digital and/or quantum processors, as appropriate, executing one or more digital and/or quantum computer programs to perform functions by operating on input digital and quantum data and generating output. The processes and logic flows may also be performed by, and apparatus may also be implemented as, special purpose logic circuitry, e.g., an FPGA or an ASIC, or a quantum simulator, or by a combination of special purpose logic circuitry or quantum simulators and one or more programmed digital and/or quantum computers.

For a system of one or more digital and/or quantum computers or processors to be “configured to” or “operable to” perform particular operations or actions means that the system has installed on it software, firmware, hardware, or a combination of them that in operation cause the system to perform the operations or actions. For one or more digital and/or quantum computer programs to be configured to perform particular operations or actions means that the one or more programs include instructions that, when executed by digital and/or quantum data processing apparatus, cause the apparatus to perform the operations or actions. A quantum computer may receive instructions from a digital computer that, when executed by the quantum computing apparatus, cause the apparatus to perform the operations or actions.

Digital and/or quantum computers suitable for the execution of a digital and/or quantum computer program may be based on general or special purpose digital and/or quantum microprocessors or both, or any other kind of central digital and/or quantum processing unit. Generally, a central digital and/or quantum processing unit will receive instructions and digital and/or quantum data from a read-only memory, or a random access memory, or quantum systems suitable for transmitting quantum data, e.g. photons, or combinations thereof.

Some example elements of a digital and/or quantum computer are a central processing unit for performing or executing instructions and one or more memory devices for storing instructions and digital and/or quantum data. The central processing unit and the memory may be supplemented by, or incorporated in, special purpose logic circuitry or quantum simulators. Generally, a digital and/or quantum computer will also include, or be operatively coupled to receive digital and/or quantum data from or transfer digital and/or quantum data to, or both, one or more mass storage devices for storing digital and/or quantum data, e.g., magnetic, magneto-optical disks, or optical disks, or quantum systems suitable for storing quantum information. However, a digital and/or quantum computer need not have such devices.

Digital and/or quantum computer-readable media suitable for storing digital and/or quantum computer program instructions and digital and/or quantum data include all forms of non-volatile digital and/or quantum memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks; and quantum systems, e.g., trapped atoms or electrons. It is understood that quantum memories are devices that may store quantum data for a long time with high fidelity and efficiency, e.g., light-matter interfaces where light is used for transmission and matter for storing and preserving the quantum features of quantum data such as superposition or quantum coherence.

Control of the various systems described in this specification, or portions of them, may be implemented in a digital and/or quantum computer program product that includes instructions that are stored on one or more non-transitory machine-readable storage media, and that are executable on one or more digital and/or quantum processing devices. The systems described in this specification, or portions of them, may each be implemented as an apparatus, method, or electronic system that may include one or more digital and/or quantum processing devices and memory to store executable instructions to perform the operations described in this specification.

While this specification contains many specific implementation details, these should not be construed as limitations on the scope of what may be claimed, but rather as descriptions of features that may be specific to particular implementations. Certain features that are described in this specification in the context of separate implementations may also be implemented in combination in a single implementation. Conversely, various features that are described in the context of a single implementation may also be implemented in multiple implementations separately or in any suitable sub combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems may generally be integrated together in a single software product or packaged into multiple software products.

Particular implementations of the subject matter have been described. Other implementations are within the scope of the following claims. For example, the actions recited in the claims may be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A cryogenic cooling system for a quantum computing system, the cryogenic cooling system comprising a plurality of stages, each stage associated with an operating temperature, each stage being progressively cooler when moving from a first stage of the plurality of stages to a subsequent stage of the plurality of stages, wherein the first stage of the plurality of stages is associated with an operating temperature of about 60 kelvin or greater.

2. The cryogenic cooling system of claim 1, wherein the first stage is associated with an operating temperature of about 80 kelvin or greater.

3. The cryogenic cooling system of claim 1, wherein the first stage is associated with an operating temperature in a range of about 80 kelvin to about 100 kelvin.

4. The cryogenic cooling system of claim 1, wherein each stage comprises a cooling unit and a thermal plate thermally coupled to the cooling unit.

5. The cryogenic cooling system of claim 1, wherein the plurality of stages further comprise a second stage, a third stage, a fourth stage, a fifth stage, a sixth stage, and a seventh stage.

6. The cryogenic cooling system of claim 5, wherein the second stage is associated with an operating temperature in a range of about 40 kelvin to about 60 kelvin.

7. The cryogenic cooling system of claim 5, wherein the third stage is associated with an operating temperature in a range of 10 kelvin to about 20 kelvin.

8. The cryogenic cooling system of claim 5, wherein the fourth stage is associated with an operating temperature in a range of about 2.5 kelvin to about 4.2 kelvin.

9. The cryogenic cooling system of claim 5, wherein the fifth stage is associated with an operating temperature in a range of about 600 millikelvin to about 800 millikelvin.

10. The cryogenic cooling system of claim 5, wherein the sixth stage is associated with an operating temperature in a range of about 100 millikelvin to about 300 millikelvin.

11. The cryogenic cooling system of claim 5, wherein the seventh stage is associated with an operating temperature of about 10 millikelvin to about 100 millikelvin.

12. The cryogenic cooling system of claim 1, wherein at least one of the plurality of stages comprises a wiring port configured to couple a signal line with a corresponding stage of a second cryogenic system.

13. The cryogenic cooling system of claim 1, further comprising a dilution refrigerator with series connected mixing stages.

14. The cryogenic cooling system of claim 13, wherein a first mixing stage of the series connected mixing stages is thermally coupled to a thermal plate of a cooling stage associated with quantum hardware.

15. The cryogenic cooling system of claim 14, wherein a second mixing stage of the series connected mixing stages is thermally coupled to a thermal plate of an intermediate cooling stage of the cryogenic cooling system.

16. A quantum computing system comprising:
one or more superconducting qubits;
one or more classical processors;
one or more signal lines coupled between the one or more superconducting qubits and the one or more classical processors;
one or more cryogenic cooling systems according to claim 1 configured to cool the superconducting qubits.

17. The quantum computing system of claim 16, wherein the one or more cryogenic cooling systems comprise a first cryogenic cooling system and a second cryogenic cooling system.

18. The quantum computing system of claim 17, wherein the first cryogenic cooling system and the second cryogenic cooling system comprises consistent cooling stages.

19. The quantum computing system of claim 17, wherein one or more stages of the first cryogenic cooling system comprise a wiring port configured to couple a signal line to a wiring port of a corresponding stage of the second cryogenic cooling system.

20. The quantum computing system of claim 17, wherein the first cooling stage and the second cooling stage are associated with different manufacturers.
